(19) United States
(12) Patent Application Publication
(10) Pub. No.: US 2023/0108280 A1
(43) Pub. Date: Apr. 6, 2023

(54) MODULAR REACTION CHAMBER

(71) Applicant: ASM IP Holding B.V., Almere (NL)

(72) Inventors: Ruchik Bhatt, Chandler, AZ (US); Jianqiu Huang, Phoenix, AZ (US)

(21) Appl. No.: 17/955,816

(22) Filed: Sep. 29, 2022

Related U.S. Application Data
(60) Provisional application No. 63/251,787, filed on Oct. 4, 2021.

(51) Int. Cl. H01L 21/687; H01L 21/67

(52) U.S. Cl. CPC H01L 21/68785; H01L 21/67103; H01L 21/67109; H01L 21/68742

(57) ABSTRACT

A modular reaction chamber configured to enable installation of two or more susceptors that are each designed for use in differing temperature ranges (e.g., at differing maximum temperatures). The modular chamber is designed to allow the first and second susceptors and their corresponding heaters to be swapped out or installed to suit the application need (e.g., a low temperature process and a high temperature process). The reaction chamber includes a body adapted, e.g., with an opening in a lower portion of the body, for receiving two or more adaptor or interface plates (or plate assemblies). Each of the plates or plate assemblies is configured for use with a particular susceptor heater assembly (e.g., low temperature heater and high temperature heater and so on) including providing proper cooling and to seal the opening in the lower portion of the reaction chamber body.

### CROSS-REFERENCE TO RELATED APPLICATIONS

This application is a nonprovisional of, and claims priority to and the benefit of, U.S. Provisional Pat. Application No. 63/251,787, filed Oct. 4, 2021 and entitled “MODULAR REACTION CHAMBER,” which is hereby incorporated by reference herein.

### FIELD OF THE DISCLOSURE

The present disclosure relates generally to methods and systems for providing surface cleaning and etching in a wafer processing or reactor system, and, more particularly, to a reaction chamber adapted for supporting cleaning and/or etching at a wafer surface at two or more temperatures ranges.

### BACKGROUND OF THE DISCLOSURE

Semiconductor processing techniques, including atomic layer deposition (ALD) and chemical vapor deposition (CVD), are often used for forming thin films of materials on substrates, such as silicon wafers. To carry out such processing, reactor systems or tools are used that have a reaction chamber in which a susceptor or substrate holder is positioned and used for holding wafers during wafer processing steps.

Exemplary processing step in a reaction chamber is cleaning and etching, and these processes may need to be carried out at a wide range of temperatures to be effective or to provide a desired reaction rate to achieve throughput demands. In one particular example, a reaction chamber may be used for clean and/or etch of the native oxide at a wafer surface supported upon the susceptor or substrate holder. The clean/etch process is useful for providing a high quality wafer base for the deposition of a metal layer, a metal nitrite layer, a metal carbide layer, or the like.

Conventionally, reaction chambers are designed and manufactured to operate within particular ranges of operating temperatures, which may limit their functionality. For example, a number of reaction chambers presently in use can be used for processes such as etch/clean, but only in a range with a maximum temperature of 250° C. or the like. This temperature range limits the process reaction rate, which, in turn, can prevent such a reaction chamber from being able to achieve desired production throughput goals.

Hence, there is a demand for reaction chamber designs for use in a reactor system that are adapted to support processing operations, including wafer clean/etch, at two or more temperature ranges such as a range capped at a maximum temperature of 450° C. and also at a range capped at a maximum of 250° C.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Briefly, the inventors recognized that there are many reactor system applications in which it is desirable to have a reaction chamber that is operable both at relatively high maximum temperatures (e.g., a range of up to 450° C. or the like) to achieve higher reaction rates or meet other processing needs and at relatively low maximum temperatures (e.g., a range of up to 250° C. or another temperature significantly (e.g., 150 to 250° C. below the higher maximum temperature)). To this end, a modular reaction chamber is described herein that is configured to enable installation of two or more susceptors that are each designed for use in differing temperature ranges (e.g., at differing maximum temperatures). For example, a first susceptor may be a nickel-chromium-molybdenum-tungsten alloy (e.g., C22 or the like) susceptor, which can be used at a reaction temperature upper limit of 450° C., and a second susceptor may be an aluminum (Al) susceptor, which can be used at a reaction temperature upper limit of 250° C.

The modular chamber is designed to allow the first and second susceptors and their corresponding heaters to be swapped out or installed to suit the application need (e.g., a low temperature process and a high temperature process) of an operator of a reactor system that includes the new reaction chamber. The reaction chamber includes a body adapted, e.g., with an opening in a lower portion of the body, for receiving two or more adaptor plates (or adaptor plate assemblies). Each of the adaptor plates or plate assemblies is configured for use with a particular susceptor heater assembly (e.g., low temperature heater and high temperature heater and so on) including providing proper cooling (e.g., temperature control) and to seal the opening in the lower portion of the reaction chamber body (or seal the lower reaction space). In the above example, the modular reaction chamber is compatible with both an Al susceptor heater assembly and with a C22 susceptor heater assembly depending on the application or insertion of a different adaptor plate.

More specifically, the present description provides a modular reaction chamber assembly. The assembly includes a reaction chamber with a body having a sidewall defining a reaction space extending through the body. The body further includes a bottom wall with an opening to the reaction space. The assembly also includes an interface plate assembly including an interface plate detachably coupled to the bottom wall and at least partially received in the opening to the reaction space to enclose the reaction space.

In some embodiments of the assembly, the interface plate is configured for use with a first susceptor heater adapted for a first upper temperature limit or for use with a second susceptor heater adapted for a second upper temperature limit greater than the first upper temperature limit. In these implementations, the first upper temperature limit may be less than about 250° C. while the second upper temperature limit may be less than about 450° C.

In these or other embodiments of the assembly, the interface plate includes a central opening coupled to a sleeve, and the first or the second susceptor heater is received at least partially in the sleeve and extends through the central opening into the reaction space. It may be useful for the body to be formed of aluminum and the interface plate to be formed of stainless steel. In some implementations, the interface plate is detachably coupled to the body with fasteners mating with the bottom wall.

In some cases, the interface plate includes a cooling tube channel extending at least once about a center of the interface plate and the interface plate assembly further includes a cooling loop positioned in the cooling tube channel and adapted for receiving a flow of coolant to control a temperature of the interface plate. Then, the cooling tube channel may be proximate (such as with a separation distance in the range of 2 to 12 mm, the range of 3 to 12 mm, or, in some cases, 6 to 12 mm) to at least one of a first sealing member used to provide a seal between an upper surface of the interface plate and the bottom wall and a second sealing member used to provide a seal between a lower surface of the interface plate and a lift pin mechanism abutting the lower surface.

Further, it can be desirable for the assembly to include a flexible heater, and the body of the chamber may include a groove in a surface of the bottom wall in which the flexible heater is received. In some cases, the groove extends about the periphery of the opening to the reaction space, whereby a temperature of the reaction space is at least partially controlled by operation of the flexible heater.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) discussed.

### BRIEF DESCRIPTION OF THE DRAWING FIGURES

While the specification concludes with claims particularly pointing out and distinctly claiming what are regarded as embodiments of the disclosure, the advantages of embodiments of the disclosure may be more readily ascertained from the description of certain examples of the embodiments of the disclosure when read in conjunction with the accompanying drawings. Elements with the like element numbering throughout the figures are intended to be the same.

FIG. 1 is a top perspective cross-sectional view of a portion of a reaction chamber assembly with an interface plate assembly of the present description.

FIG. 2 illustrates a cooling loop or tubing run that may be provided in a lower surface of an interface plate of the present description such as the one shown in FIG. 1.

FIG. 3 illustrates a cooling collar or loop that may be provided about a center sleeve or conduit (and heating element contained therein) of an interface plate assembly of the present description such as the one shown in FIG. 1.

FIG. 4 is a side sectional view of the reaction chamber of FIG. 1 showing further details of modifications used to make it modular.

FIG. 5 is an enlarged partial view of the reaction chamber of FIG. 4 showing interface plate mating surfaces and/or components in more detail.

FIG. 6 is a top perspective view of the interface plate of FIG. 1.

FIG. 7 is a bottom perspective view of the interface plate assembly of FIGS. 1 and 6.

FIG. 8 is an enlarged side sectional view of an outer portion of the interface plate of FIG. 6.

FIG. 9 is a side sectional view of the reaction chamber assembly of FIG. 1 showing it further assembled with components interfacing with the interface plate assembly.

FIG. 10 is an enlarged partial view of the reaction chamber assembly of FIG. 9 illustrating placement of cooling channels around O-rings/sealing members used to seal with lift pin mechanism.

FIG. 11 is a top perspective view of a dual chamber configured for use with the adapter plate assemblies of the present description.

### DETAILED DESCRIPTION

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

As described in greater detail below, various details and embodiments of the disclosure may be utilized in conjunction with a reactor system with one or more of the new modular reaction chambers configured for wafer clean/etch processes and/or for a multitude of deposition processes, including but not limited to, ALD, CVD, metalorganic chemical vapor deposition (MOCVD), molecular beam epitaxy (MBE), physical vapor deposition (PVD), plasma-enhanced chemical vapor deposition (PECVD), and plasma etching. The embodiments of the disclosure may also be utilized in semiconductor processing systems configured for processing a substrate with a reactive precursor, which may also include etch processes, such as, for example, reactive ion etching (RIE), capacitively coupled plasma etching (CCP), and electron cyclotron resonance etching (ECR).

The inventors recognized that it is desirable to provide reaction or process chamber assembly or unit that is adapted to support processes, such as clean/etch and the like, that may be carried out at two or more temperature ranges (or with two different upper temperature limits). To this end, it may be desirable to use susceptors and corresponding heaters suited to such differing temperature ranges. For example, an Al susceptor may be used with a lower temperature heater assembly (e.g., with a maximum temperature of 250° C.) while a C22 susceptor may be used with a higher temperature heater assembly (e.g., with a maximum temperature of 450° C.). In the past, a reaction chamber was designed for each temperature range and susceptor heater assembly. The inventors designed a reaction or process chamber assembly that is “modular” in that the reaction chamber is configured to receive one of two or more interface plate assemblies so that differing susceptors and the corresponding heater assemblies may be swapped out while continuing to use the same reaction or process chamber (and other associated components in some embodiments).

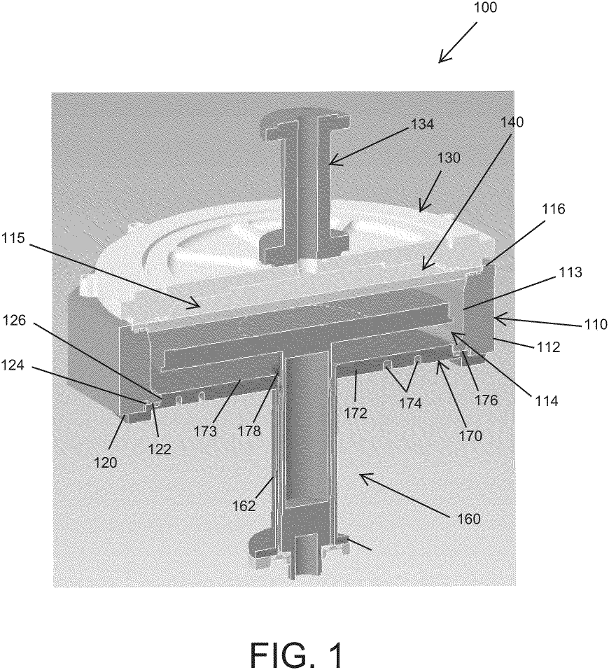

In this regard, FIG. 1 is a top perspective cross-sectional view of a portion of a reaction chamber assembly or unit 100 with an interface plate assembly 160 of the present description. The reaction chamber assembly 100 is configured for use in a variety of reactor system designs. The reaction chamber assembly 100 includes a reaction chamber 110 with a body 112 defining with an inner surface or sidewall 113 a vault or lower chamber (or lower chamber space) 114. A top surface or sidewall 116 of the body 112 is configured for receiving a susceptor 140.

An upper chamber or processing space 115 is provided above the susceptor 140 and enclosed by a showerhead lid or cap 130 of the reaction chamber assembly 100. The assembly 100 further includes a showerhead inlet 134 for providing deposition gases through the lid 130 into the processing space 115. A pedestal heater 150 is included in the assembly 100 for heating the susceptor 140 during processing operations such as during clean/etch, and the heater 150 may take the form of a high temperature heater (e.g., one in which the upper plate is formed of C22 or the like that may be used to provide a temperature range with a higher upper limit such as one at 450° C. or the like).

Significantly, the reaction chamber assembly 100 includes an interface plate assembly 160 that is adapted to mate with the reaction chamber 110 to define the vault or lower chamber space 114 and to receive and allow the heater 150 to be positioned within the vault or lower chamber space 114 proximate to the susceptor 140. To these ends, the assembly 160 includes sleeve or conduit 162 extending up from a lower flange 164 (that may be used to mate the assembly 160 to the heater 150 or its support collar). The sleeve or conduit 162 includes an interior channel through which the heater cylindrical member may extend to its upper heating plate. The assembly 160 further includes a circular plate 170, with a central opening or hole 178 through which the heater 150 may pass to enter the vault or lower chamber space 114.

The plate 170 includes an exterior or lower surface 172 facing away from the reaction chamber 110 and susceptor 140 and an interior or upper surface 174 abutting the space 114 and facing the susceptor 140 and heater 150 (or its heat element within the space 114). The body 112 of the reaction chamber 110 has a bottom surface or sidewall 120 that is configured to receive the plate 170 within a lower opening or aperture defined by inner lip or ridge 126, which abuts or is proximate to an outer or peripheral edge of the plate 170.

To achieve a seal, paired surfaces 122 and 176 are provided on the bottom surface/sidewall 120 of the reaction chamber body 110 and a peripheral lip or extension member of the upper surface 173 of the plate 170. An O-ring or other sealing member (not shown) may be positioned between these two surface 122 and 176 and extend in a continuous manner about plate 170.

To control temperatures of the plate 170 and/or the vault or lower chamber space 114, it may be desirable to provide cooling and heating features. With this in mind, a groove or channel (recessed surface) 124 is provided in the bottom surface/sidewall 120 of the reaction chamber body 110, and a flexible (or other) heater or heating element (not shown in FIG. 1) would be inserted within the groove or channel 124. Typically, the heater and groove 124 would extend about the entire periphery of vault or lower chamber space 114 and acts to heat the body 112 and, in turn, the vault or lower chamber space 114.

To provide cooling to maintain a desired temperature of the plate 170, the plate 170 includes grooves or channels (recessed surfaces) 174 that extend in a circuitous path about the lower surface 172 of the plate 170 on both sides of the heater’s central element. Tubing (not shown in FIG. 1) through which coolant (e.g., cooling water) would flow during operation of the assembly 100 would be disposed in the groove/channel 174, and this coolant flow can be used to control the temperature of the plate 170.

As noted above, the assembly 100 may be configured for a relatively high upper temperature limit, such as 450° C. The components of the assembly 100 may be fabricated of a variety of materials for use in such a higher temperature application. For example, but not as a limitation, the susceptor 140 and heater 150 may be formed of C22, the interface plate assembly 160 may be formed of stainless steel (e.g., 316 SS or the like), and the reaction chamber 110 may be formed of aluminum (e.g., 6061 Al or the like).

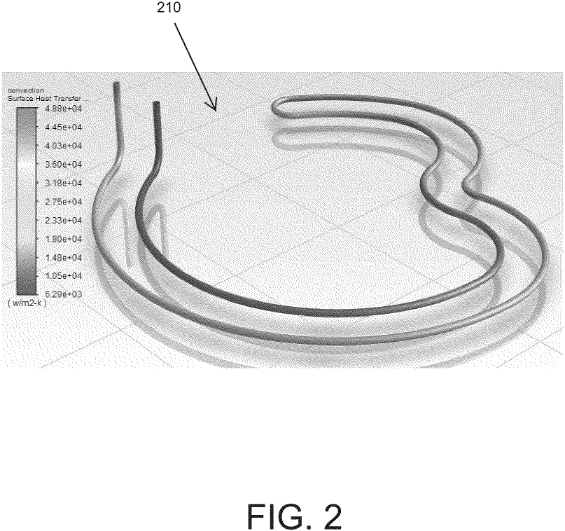

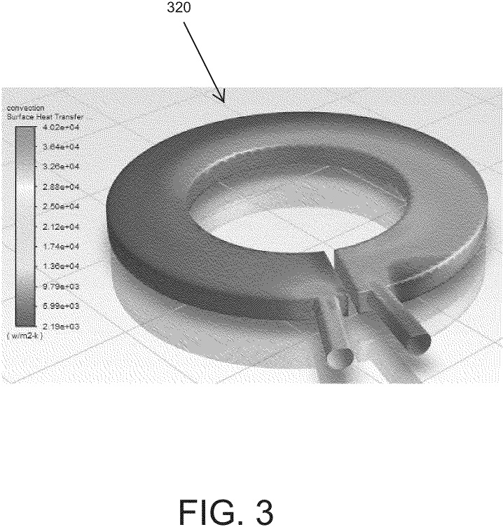

The heat transfer characteristics of these components fabricated of particular materials along with expected heat generation by the heater 150 and air flow and other characteristics of the assembly 100 were used to perform evaluations to ensure that adequate cooling as well as heating is provided within the new assembly 100. FIG. 2 illustrates a coolant loop or coolant tubing 210 (e.g., 0.25-inch SS tubing or the like) that may be positioned in the groove/channel 174 of the plate 170 (with thermal paste provided between the channel walls and tubing to achieve enhanced thermal conductivity) to cool the plate 170, such as with a flow of water (or other coolant) of 10 liters per minute (or other flow rate) at 30° C. inlet (or a lower or higher temperature inlet) to achieve desired cooling of the plate 170. Additional cooling may be provided in the assembly 100 by addition of a cooling collar 320 as shown in FIG. 3, and this collar 320 would be positioned in the assembly 100 to encircle the sleeve/conduit 162 of the interface plate assembly 160. Coolant flow similar to that provided for cooling loop 210 may be provided in collar 320 to achieve desirable results.

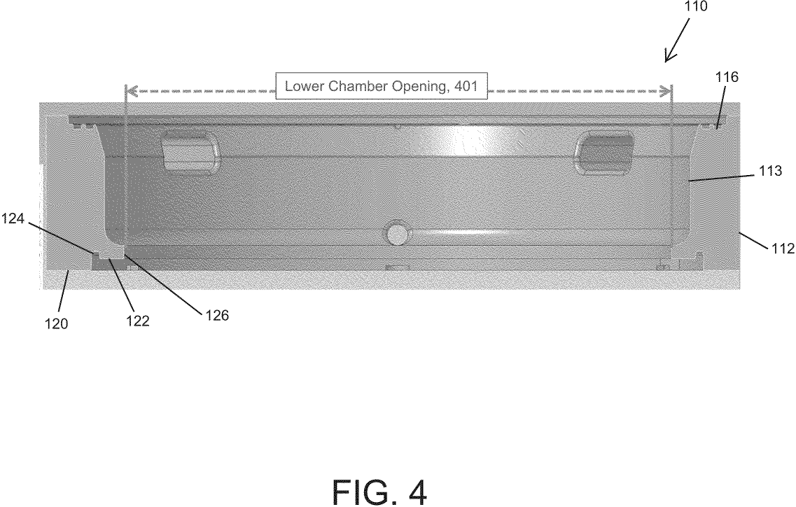

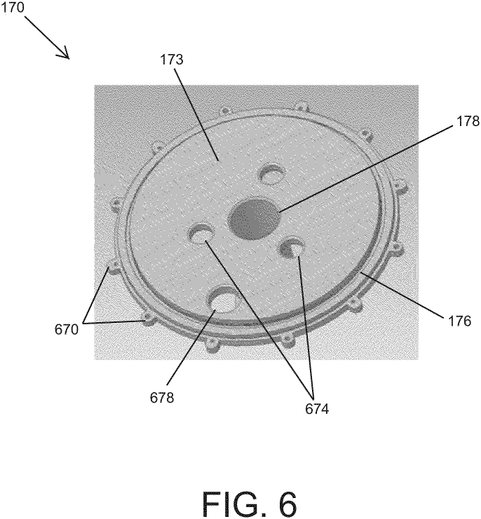

FIG. 4 is a side sectional view of the reaction chamber 110 of FIG. 1 showing further details of modifications used to make it modular. Particularly, a conventional process chamber is nearly wholly enclosed with a bottom wall with several ports. In contrast, as shown at 401, material is removed to create an opening at the bottom portion of the sidewall 112 of the chamber 110. Particularly, a circular lower opening or aperture is defined by inner lip or ridge 126 of the bottom surface or sidewall 120, which abuts or is proximate to an outer or peripheral edge of the plate 170 upon assembly as shown in FIG. 1. Hence, the inner diameter of this aperture would match or be slightly larger than the outer diameter of the interface or plate 170 (or at least of its upper/inner portion excluding the external mating shelf used to provide the O-ring mating surface/groove 176 (as shown in FIG. 1) and fastener receptacles (which are shown at 670 in FIG. 6).

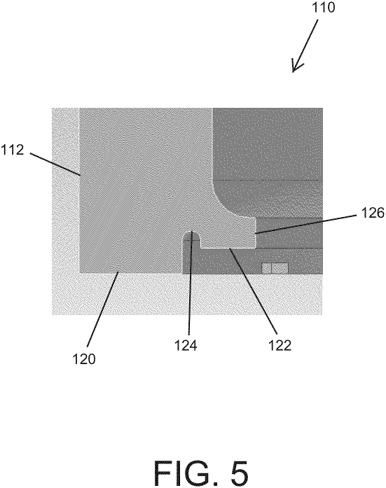

FIG. 5 is an enlarged partial view of the reaction chamber 110 of FIG. 4 showing interface plate mating surfaces and/or components in more detail. Particularly, O-ring mating surface 122 is shown in additional detail, and this surface would be used to mate with an O-ring positioned within a corresponding groove on the upper surface of the interface plate, and the surface/ledge 122 is recessed a small distance from other portions of the bottom surface or sidewall 120. FIG. 5 is also useful for showing the location of the groove 124 in the reaction chamber side wall 112 that is used to receive a heater to maintain vault temperatures, and this may take the form of a flexible heater that would extend in the groove 124 about the entire sidewall circumference (and, therefore, about the periphery of the interface plate once it is received upon the bottom surface or sidewall 120.

FIG. 6 is a top perspective view of the interactive plate 170 of FIG. 1. FIG. 6 is useful for showing additional details of the plate or disk 170 including the inclusion of fastener receptacles 670 about the periphery or on the edge of the plate 170. These are used, with fasteners (not shown such as screws), to detachably attach the plate 170 and interface plate assembly 160 to the bottom surface or sidewall 120 of the reaction chamber 110. The assembly 100 is “modular” in that different interface plate assemblies may be used in place of or swapped in for assembly 160 such as to support a different susceptor heater (and susceptor) such as one useful for lower temperature ranges (e.g., for an upper limit of 250° C.).

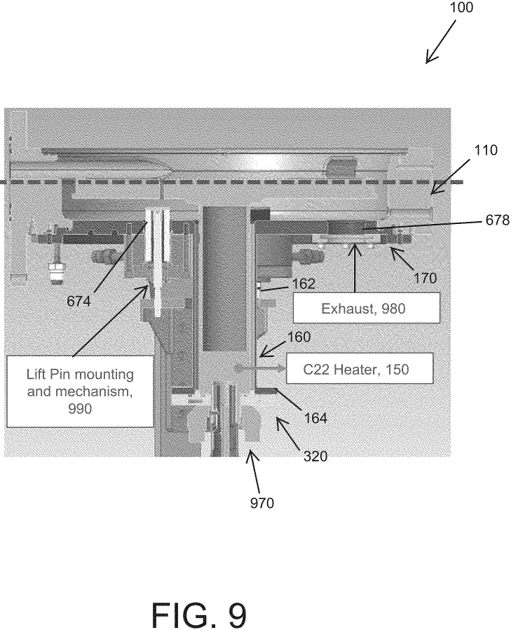

As shown in FIG. 6, the plate 170 further includes a set of ports 674, which may be used to receive and/or mate with lift pin mechanisms (shown in FIG. 9) such that these mechanisms may be positioned in the vault or lower chamber space with a seal formed between the lift pin mechanism or its mount and a lower surface 172 of the plate 170. Additionally, an exhaust port 678 is included in the plate 170 to provide an outlet for discharge gases, and an exhaust system inlet may be attached to the lower surface 172 of the plate 170 at this port 678.

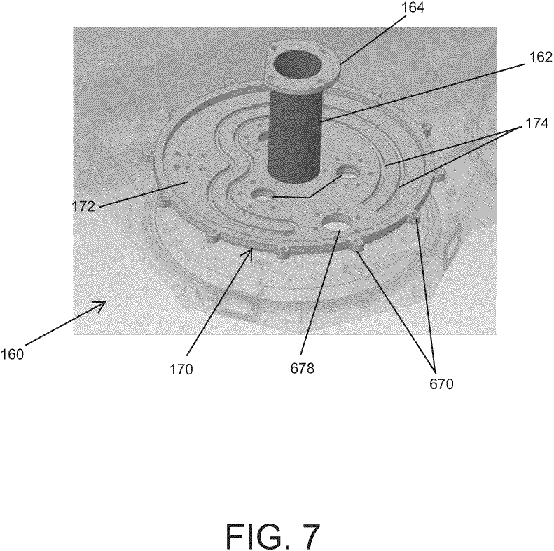

FIG. 7 is a bottom perspective view of the interface plate assembly 160 of FIG. 1. FIG. 7 again shows the fastener receptacles 670 about the external edge of the plate 170, the lift pin ports 674 positioned about the periphery of center sleeve 162, and the exhausts port 678 provided radially outward from the lift pin ports 674. Additionally, the grooves or recessed surfaces 174 are shown in lower surface 172, and these are used to receive the cooling loop 210 shown in FIG. 2. As shown, the loop 210 and grooves 174 can follow a circuitous path and are generally radially outward from the lift pin ports 674. Further, in some preferred embodiments, the grooves 174 and loop 210 are disposed proximate to (e.g., within 10 to 20 mm) of the placement of sealing members or O-rings, which may be formed Kalrez® or other materials useful for O-rings (e.g., the O-ring used to provide a seal between the plate 170 and the process chamber bottom surface or sidewall 120 and/or the O-rings used to provide a seal between the plate 170 and the lift pin mechanisms).

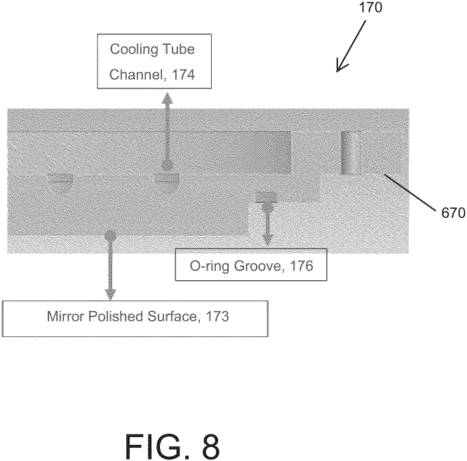

FIG. 8 is an enlarged side sectional view of an outer portion of the interface plate 170. This figure shows the fastener receptacle 670 at the edge of the plate 170. Additionally, cooling tube channel or groove 174 is shown additional detail on surface 172 of the plate 170, and the depth and/or diameter of this channel 174 is chosen to be about the outer diameter of the tubing used for the coolant loop 210 (such as when a press fit is used to obtain good heat transfer) or a predefined amount larger to provide contact but ensure the loop 210 can be positioned in the channel 174. FIG. 8 also further clarifies the position of the O-ring groove 176 on the upper surface 173 of the plate 170 and disposed about the periphery of the circular center or raised pedestal portion of the disk/plate 170. As shown in FIG. 8, the upper surface 173 of the plate 170 may be mirror polished so that it can act as a reflector in the reaction chamber assembly 100.

FIG. 9 is a side sectional view of the reaction chamber assembly 100 of FIG. 1 showing it further assembled with components interfacing with the interface plate assembly 160. In addition to the components shown in FIG. 1, the assembly 100 in FIG. 9 is shown to include the coolant collar or flange 320. It is positioned so as to mate with the flange 164 of the interface plate assembly 160, and it may be water cooled to provide cooling to portions of the pedestal (or C22) heater 150. A clamping mechanism 970 may further be used to mount the cooling collar and/or flange 164 within the reaction chamber assembly 100 as shown. Further, as shown, an exhaust inlet element 980 may be attached to the exhaust port 678 of the interface plate 170 to discharge gas from the lower chamber space 114 (seen in FIG. 1).

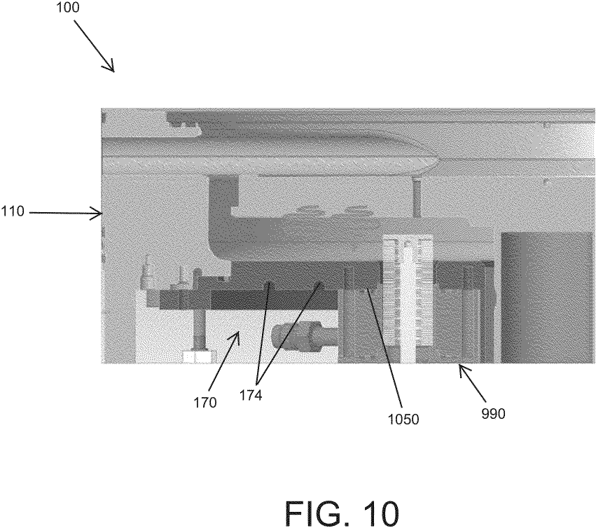

Additionally, FIG. 9 shows a lift pin mechanism 990 received, at least partially, in the lift pin port 674 of the interface plate 170. To provide a gas seal between the plate 170 and the lift pin mechanism 990, FIG. 10 illustrates, with an enlarged view, that O-ring grooves 1050 may be provided in an upper surface of the lift pin mechanism 990 and/or in the lower surface 172 of the interface plate 170. Further, as noted above, one or more of the cooling channels 174 (in which tubing of coolant loop 210 would be disposed) run proximate (e.g., within about 3 to 12 mm) to the O-rings (not shown) in grooves 1050.

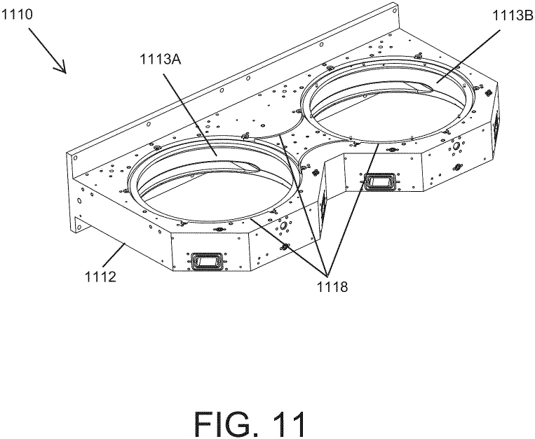

The concepts described with reference to FIGS. 1-10 may be provided in a single chamber reactor system or tool or in systems that utilize two or more processing chambers. For example, FIG. 11 is a top perspective view of a dual chamber 1110 configured for use with the adapter plate assemblies of the present description. To provide a dual chamber configuration rather than the single shown in FIG. 1, the process chamber 1110 includes a body 1112 configured with two spaced apart interior or inner surfaces or sidewalls 1113A and 1113B that are adapted similar to surface/sidewall 113 of FIG. 1 to receive a susceptor or substrate holder at an upper end and to define a vault or lower chamber space upon installation of an interface plate assembly (not shown but understood from assembly 160 in FIG. 1) onto the body 1112.

To manage vault temperatures, circumferential grooves or channels 1118 are provided in surface of the body 1112. These grooves/channels 1118 extend about the periphery of each chamber aperture or opening in the body 1112 defined by inner surfaces or sidewalls 1113A and 1113B. One or more flexible heaters may be inserted into the grooves/channels 1118 and operated to manage temperatures of the body 1112 as desired during processing.

The openings/apertures defined by inner surfaces or sidewalls 1113 allow nearly any susceptor heater to be utilized as the bottom of the chamber 1112 is open. The same heater (low temperature, high temperature, or a temperature between these two) may be used in both chambers of the dual chamber 1110 or they may differ with one being higher and one being lower to support two different temperature ranges with use of the dual chamber 1110 in a reactor system.

Benefits, other advantages, and solutions to problems have been described herein with regard to specific embodiments. However, the benefits, advantages, solutions to problems, and any elements that may cause any benefit, advantage, or solution to occur or become more pronounced are not to be construed as critical, required, or essential features or elements of the disclosure.

Reference throughout this specification to features, advantages, or similar language does not imply that all of the features and advantages that may be realized with the present disclosure should be or are in any single embodiment of the invention. Rather, language referring to the features and advantages is understood to mean that a specific feature, advantage, or characteristic described in connection with an embodiment is included in at least one embodiment of the subject matter disclosed herein. Thus, discussion of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize that the subject matter of the present application may be practiced without one or more of the specific features or advantages of a particular embodiment. In other instances, additional features and advantages may be recognized in certain embodiments that may not be present in all embodiments of the disclosure. Further, in some instances, well-known structures, materials, or operations are not shown or described in detail to avoid obscuring aspects of the subject matter of the present disclosure. No claim element is intended to invoke 35 U.S.C. 112(f) unless the element is expressly recited using the phrase “means for.”

The scope of the disclosure is to be limited by nothing other than the appended claims, in which reference to an element in the singular is not intended to mean “one and only one” unless explicitly so stated, but rather “one or more.” It is to be understood that unless specifically stated otherwise, references to “a,” “an,” and/or “the” may include one or more than one and that reference to an item in the singular may also include the item in the plural. Further, the term “plurality” can be defined as “at least two.” As used herein, the phrase “at least one of”, when used with a list of items, means different combinations of one or more of the listed items may be used and only one of the items in the list may be needed. The item may be a particular object, thing, or category. Moreover, where a phrase similar to “at least one of A, B, and C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A, B, and C. In some cases, “at least one of item A, item B, and item C” may mean, for example, without limitation, two of item A, one of item B, and ten of item C; four of item B and seven of item C; or some other suitable combination.

All ranges and ratio limits disclosed herein may be combined. Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Any reference to attached, fixed, connected or the like may include permanent, removable, temporary, partial, full and/or any other possible attachment option. Additionally, any reference to without contact (or similar phrases) may also include reduced contact or minimal contact. In the above description, certain terms may be used such as “up,” “down,” “upper,” “lower,” “horizontal,” “vertical,” “left,” “right,” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

Although exemplary embodiments of the present disclosure are set forth herein, it should be appreciated that the disclosure is not so limited. For example, although reactor systems are described in connection with various specific configurations, the disclosure is not necessarily limited to these examples. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. A modular reaction chamber assembly, comprising:
a reaction chamber with a body having a sidewall defining a reaction space extending through the body, wherein the body further includes a bottom wall with an opening to the reaction space; and
an interface plate assembly including an interface plate detachably coupled to the bottom wall and at least partially received in the opening to the reaction space to enclose the reaction space.

2. The modular reaction chamber assembly of claim 1, wherein the interface plate is configured for use with a first susceptor heater adapted for a first upper temperature limit or for use with a second susceptor heater adapted for a second upper temperature limit greater than the first upper temperature limit.

3. The modular reaction chamber assembly of claim 2, wherein the first upper temperature limit is less than about 250° C. and wherein the second upper temperature limit is less than about 450° C.

4. The modular reaction chamber assembly of claim 2, wherein the interface plate comprises a central opening coupled to a sleeve and wherein the first or the second susceptor heater is received at least partially in the sleeve and extends through the central opening into the reaction space.

5. The modular reaction chamber assembly of claim 2, wherein the body is formed of aluminum and the interface plate is formed of stainless steel.

6. The modular reaction chamber assembly of claim 1, wherein the interface plate is detachably coupled to the body with fasteners mating with the bottom wall.

7. The modular reaction chamber assembly of claim 1, wherein the interface plate comprises a cooling tube channel extending at least once about a center of the interface plate and the interface plate assembly further comprises a cooling loop positioned in the cooling tube channel and adapted for receiving a flow of coolant to control a temperature of the interface plate.

8. The modular reaction chamber assembly of claim 7, wherein the cooling tube channel is positioned at a distance in the range of 6 to 12 millimeters (mm) from at least one of a first sealing member used to provide a seal between an upper surface of the interface plate and the bottom wall and a second sealing member used to provide a seal between a lower surface of the interface plate and a lift pin mechanism abutting the lower surface.

9. The modular reaction chamber assembly of claim 1, further comprising a flexible heater and wherein the body comprises a groove in a surface of the bottom wall in which the flexible heater is received, and wherein the groove extends about the periphery of the opening to the reaction space, whereby a temperature of the reaction space is at least partially controlled by operation of the flexible heater.

10. A modular reaction chamber assembly, comprising:
a reaction chamber having a sidewall defining a cylindrical reaction space, wherein the sidewall includes a bottom surface with an opening to the reaction space; and
an interface plate assembly including an interface plate detachably coupled to the bottom surface with fasteners to enclose the reaction space, wherein the interface plate assembly further includes a sealing member disposed between an upper surface of the interface plate and the bottom surface of the sidewall and extending about the periphery of the opening to the reaction space.

11. The modular reaction chamber assembly of claim 10, wherein the interface plate comprises a cooling tube channel extending about a center of the interface plate and the interface plate assembly further comprises a cooling loop positioned in the cooling tube channel and adapted for receiving a flow of coolant to control a temperature of the interface plate.

12. The modular reaction chamber assembly of claim 11, wherein the sealing member comprises an O-ring and wherein the cooling tube channel is positioned at a distance in the range of 3 to 12 mm from to the sealing member (replace with range of separation distances?).

13. The modular reaction chamber assembly of claim 10, further comprising a flexible heater and wherein the bottom surface comprises a groove in which the flexible heater is received, and wherein the groove extends about the periphery of the opening to the reaction space, whereby a temperature of the reaction space is at least partially controlled by operation of the flexible heater.

14. The modular reaction chamber assembly of claim 10, wherein the interface plate is configured for use with a first susceptor heater adapted for a first upper temperature limit or for use with a second susceptor heater adapted for a second upper temperature limit greater than the first upper temperature limit.

15. The modular reaction chamber assembly of claim 14, wherein the first upper temperature limit is less than about 250° C. and wherein the second upper temperature limit is less than about 450° C.

16. A modular reaction chamber assembly, comprising:
a reaction chamber with a body having a sidewall defining a reaction space extending through the body, wherein the body further includes a bottom wall with an opening to the reaction space; and
an interface plate assembly including a first interface plate or a second interface plate both detachably couplable to the bottom wall and configured to be at least partially received in the opening to the reaction space to enclose the reaction space,
wherein the first interface plate is configured for use with a first susceptor heater adapted for a first upper temperature limit, and
wherein the second interface plate is configured for use with a second susceptor heater adapted for a second upper temperature limit greater than the first upper temperature limit.

17. The modular reaction chamber assembly of claim 16, wherein the first upper temperature limit is less than about 250° C. and wherein the second upper temperature limit is less than about 450° C.

18. The modular reaction chamber assembly of claim 16, wherein the first and second interface plates each comprises a central opening coupled to a sleeve and wherein the first or the second susceptor heater is received at least partially in the sleeve and extends through the central opening into the reaction space.

19. The modular reaction chamber assembly of claim 16, wherein the first and second interface plates each comprises a cooling tube channel and the interface plate assembly further comprises a cooling loop positioned in the cooling tube channel and adapted for receiving a flow of coolant to control a temperature of the interface plate.

20. The modular reaction chamber assembly of claim 19, wherein the cooling tube channel is positioned at a distance in the range of within 3 to 12 mm from at least one of a first sealing member used to provide a seal between an upper surface of the first interface plate or the second interface plate and the bottom wall and a second sealing member used to provide a seal between a lower surface of the first interface plate or the second interface plate and a lift pin mechanism abutting the lower surface.
